(19) United States
(12) Patent Application Publication
(10) Pub. No.: US 2016/0288169 A1
(43) Pub. Date: Oct. 6, 2016

(54) ULTRASONIC TRANSDUCER AND MANUFACTURING METHOD THEREFOR

(71) Applicant: ALPINION MEDICAL SYSTEMS CO., LTD., Seoul (KR)

(72) Inventors: Beom-Seok BAE, Daegu (KR); Keon-Ho SON, Seongnam-si (KR)

(73) Assignee: ALPINION MEDICAL SYSTEMS CO., LTD., Seoul (KR)

(21) Appl. No.: 15/035,187

(22) PCT Filed: Nov. 6, 2013
(86) PCT No.: PCT/KR2013/010016

§ 371 Date: May 6, 2016

(51) Int. Cl. B06B 1/06; H01L 41/253

(52) U.S. Cl. CPC B06B 1/0644; H01L 41/253

(57) ABSTRACT

An ultrasonic transducer and a manufacturing method therefor are disclosed. The ultrasonic transducer, according to one embodiment of the present invention, comprises: an ultrasonic transducer body generating ultrasonic waves by using an active element to externally irradiate the ultrasonic waves through a lens part, and receiving reflected waves of the externally irradiated ultrasonic waves to convert the reflected waves into electrical signals; and a backing block joined to the opposite side of at least the lens part of the ultrasonic transducer body so as to attenuate the ultrasonic waves. According to one embodiment of the present invention, a backing material of the backing block is composed of a damping grease mixture. The damping grease mixture can be a material in which metal powder is mixed as a filler by using the damping grease as a dispersion medium. For example, the damping grease can be a mixture in which polytetrafluoroethylene (PTFE) is mixed as a viscosity increasing agent. The metal powder can contain at least one of tungsten (W), manganese (Mn), lead (Pb), and zinc oxide (ZnO).

### TECHNICAL FIELD

The present invention relates to an ultrasonic transducer that uses ultrasound waves for obtaining image information of the inside of an object, and a manufacturing method of said transducer.

### BACKGROUND ART

An ultrasonic probe is a component of an ultrasonic diagnostic apparatus that obtains image information about an area that is being examined. The ultrasonic probe acquires image information about an object's examination area by transmitting ultrasonic signals into said examination area and receiving ultrasonic signals reflected from the boundary of tissues with different acoustic impedance. The obtained image information is then output to a monitor of the ultrasonic diagnostic apparatus and a diagnostician may be able to diagnose the object based on the image information displayed on the monitor. An ultrasonic transducer is provided within the ultrasonic probe, and it is said transducer that transmits ultrasonic signals into the object being examined and receives ultrasonic signals reflected back from the object.

Generally, the ultrasonic transducer is provided with a backing material. The backing material blocks or minimizes an echo of an ultrasonic wave generated by an active element, such as a piezoelectric element, from propagating in an undesired direction, and thereby prevents any image distortion of an area that is being examined. Hence, the backing material is also referred to as an acoustic absorption layer. The backing material is generally formed as a backing block and is attached onto a rear surface of the ultrasonic transducer, i.e., a surface that is the opposite side to the surface onto which a lens is attached.

In order to effectively reduce the ultrasonic energy, the backing material is required to be one that has excellent acoustic absorption properties and whose acoustic impedance matches well with the active element (e.g., a piezoelectric element). For example, Korean Patent Application Publication No. 2012-0082642, “2-dimensional ultrasonic transducer array”, discloses a mixture in which high-density, powdered materials, such as tungsten (W), lead (Pb), zinc oxide (ZnO), etc., are added to epoxy resin and used as a backing material. However, while said material may satisfy general requirements expected of a backing material regarding acoustic absorption and acoustic impedance, it has not been in way significant. Hence, there is a need for a backing material that exhibits superior acoustic absorption properties, as well as whose acoustic impedance matches an active element.

### TECHNICAL PROBLEM

In order to provide a solution to one issue, the objective of the present invention is to provide an ultrasonic transducer that includes a backing material with excellent acoustic absorption characteristic and acoustic impedance, and a manufacturing method for said transducer.

To address another issue, the objective of the present invention is to provide an ultrasonic transducer that is outfitted with a backing material that is inexpensive and that can be manufactured to be a small size; and a manufacturing method of said ultrasonic transducer.

### TECHNICAL SOLUTION

According an exemplary embodiment of the present invention to solve the above issues, there is provided an ultrasonic transducer including: an ultrasonic transducer body configured to externally irradiate ultrasonic waves generated from an active element through a lens part and receive reflected waves of the externally irradiated ultrasonic waves to convert the reflected waves into electrical signals; and a backing block bonded to an opposite side of the lens part at the ultrasonic transducer body so as to attenuate the ultrasonic waves, wherein a backing material of the backing block is comprises of a damping grease mixture.

According to one aspect of the exemplary embodiment, the damping grease mixture may be a material in which metal powder is mixed as a filler by using the damping grease as a dispersion medium. In this case, the damping grease may be a mixture in which polytetrafluoroethylene (PTFE) is mixed as a viscosity increasing agent. In addition, the PTFE may be added at a volume ratio of 45-50% relative to a total volume of the damping grease mixture. Further, the metal powder may contain at least one of tungsten (W), manganese (Mn), lead (Pb), and zinc oxide (ZnO). In this case, the metal powder may be contained at a weight ratio of 40-70% relative to a total weight of the damping grease mixture.

According to another aspect of the exemplary embodiment, the ultrasonic transducer may further include a support substrate interposed between the ultrasonic transducer body and the backing block so as to support the ultrasonic transducer body.

According to yet another aspect of the exemplary embodiment, the backing block may include a backing block frame having an internal hollow space, and the damping grease mixture that fills inside the backing block frame.

According another exemplary embodiment of the present invention to solve the above issues, there is provided a method for manufacturing an ultrasonic transducer, including: preparing an ultrasonic transducer body and a backing block frame; bonding the prepared ultrasonic transducer body and the backing block frame to an opposite side of a lens part of the ultrasonic transducer body; and injecting a damping grease mixture into the backing block frame through an injection port on the backing block frame.

According to one aspect of the exemplary embodiment, in the injection of the damping grease mixture, the damping grease mixture may be injected using a dispenser. At this time, in the injection of the damping grease mixture, the damping grease mixture may be injected until the damping grease mixture is discharged through a discharge port on the backing block frame, and thereafter, the injection port and the discharge port are sealed.

According to another aspect of the exemplary embodiment, the bonding and the injection can be performed in a reverse order.

Additional features of the invention will be set forth in the description which follows, and in part will be apparent from the description, or may be learned by practice of the invention.

### ADVANTAGEOUS EFFECTS

According to exemplary embodiments described herein, a damping grease mixture with excellent acoustic absorption properties is used as a backing material for an ultrasonic transducer, and hence it is possible to achieve superior attenuation characteristics to an existing backing material. By doing so, an ultrasonic probe that includes the ultrasonic transducer in accordance with the exemplary embodiment of the present invention can obtain an image with less noise, increase the accuracy of diagnosis, as well as achieve excellent acoustic absorption properties even when being manufactured in a small size. Also, since the backing material has some degree of flexibility, it can usefully apply to a backing block of a small sized transducer. In addition, without making a backing block fit to the shape of the ultrasonic transducer, the ultrasonic transducer can be manufactured by first preparing a backing block frame and then inserting the baking material into said backing block frame, thereby simplifying the manufacturing process and reducing the manufacturing cost.

### DESCRIPTION OF DRAWINGS

FIG. 1 is a diagram illustrating a configuration of an ultrasonic transducer according to an exemplary embodiment of the present invention.

FIG. 2 is a flowchart illustrating a method for manufacturing the ultrasonic transducer according to an exemplary embodiment of the present invention.

FIGS. 3 to 5 are diagrams schematically illustrating procedures for manufacturing the ultrasonic transducer according to the method of FIG. 2.

### MODE FOR INVENTION

The invention is described more fully hereinafter with reference to the accompanying drawings, in which exemplary embodiments of the invention are shown. Terms described in below are selected by considering functions in the embodiment and meanings may vary depending on, for example, a user or operator's intentions or customs. Therefore, in the following embodiments, when terms are specifically defined, the meanings of terms should be interpreted based on definitions, and otherwise, should be interpreted based on general meanings recognized by those skilled in the art. It will be understood that when a first layer is referred to as being “on” or “connected to” a second layer and unless it is explicitly stated that the first layer is “directly on” or “directly connected to” the second layer, the first layer can be directly on or directly connected to the second layer, or a third layer may intervene between the first and second layers.

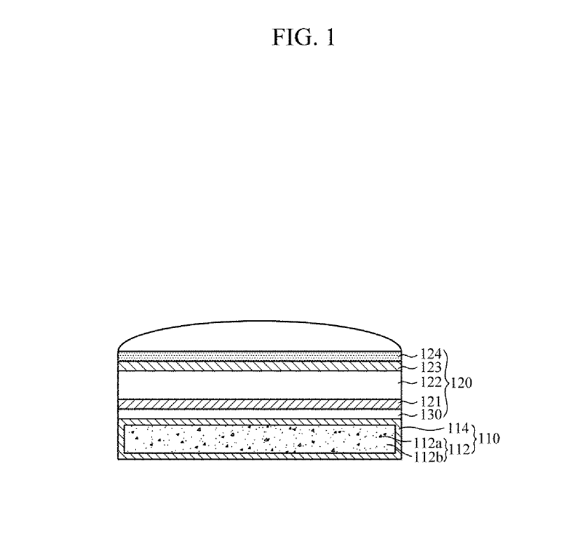

FIG. 1 is a cross-sectional view schematically showing a configuration of an ultrasonic transducer according to an exemplary embodiment of the present invention. Referring to FIG. 1, an ultrasonic transducer 100 includes a backing block 110 and an ultrasonic transducer body 120. The ultrasonic transducer body 120 includes a lower electrode unit 121, an active element 121, an upper electrode unit 123, a matching layer 124, and a lens part 125. The ultrasonic probe 100 may be either a single element transducer or an array transducer. The following description will focus on the latter, and it will be apparent to those skilled in the art that this description is only illustrative.

The ultrasonic transducer 100 may further include a supporting substrate 130 interposed between the backing block 110 and the ultrasonic transducer body 120. In the drawing, the supporting substrate 130 is illustrated as being a separate element from the ultrasonic transducer body 120, but this is only for emphasizing that the supporting substrate 130 is an optional element. That is, it may be construed that the supporting substrate 130 may be a part of the ultrasonic transducer body 120 to be attached onto the backing block 110.

The backing block 110 may be configured to allow acoustic impedance to match well with the active element 122, for example, a piezoelectric element. Also, the backing block 110 may be configured to have an enhanced acoustic absorption characteristic. By suppressing free oscillation of the active element 122, for example, a piezoelectric element, which is arrayed on an upper layer, the backing block 110 with an enhanced acoustic absorption characteristic may reduce a pulse width of ultrasonic waves, as well as block the unnecessary propagation of ultrasonic waves in an opposite direction from the lens part 125, thereby effectively preventing the image distortion.

According to an exemplary embodiment, the backing block 110 may include a backing block frame 114 and a damping grease mixture 112 filled in said backing block frame. Specifically, according to the exemplary embodiment, the damping grease mixture 112 is used as a backing material that is filled in the backing block 110 to form the backing block 110. The damping grease mixture 112 refers to a composition that contains high-density powdered materials as a filter, along with damping grease 112b as a dispersion medium. The damping grease mixture 112 typically may be in a semi-solid state with a certain degree of flexibility at room temperature. The damping grease mixture 112 will be described later in detail.

The backing block frame 114 is a container or a housing to contain the damping grease mixture 112 that has a little flexibility. According to the present exemplary embodiment, the backing block frame 114 is not particularly limited in shape, and can be properly implemented in consideration of the size, type, and characteristics of the ultrasonic probe to be manufactured. For example, the backing block frame 114 may be of a rectangular block shape (e.g., a backing block), which is only illustrative. As described below, the damping grease mixture 112 used as a backing material in accordance with the exemplary embodiment shows a superior ultrasonic wave attenuation characteristic compared to a typical backing material, and hence, even if provided with the backing block frame 114 fabricated to be small (particularly, thin), the backing block 110 can exhibit excellent attenuation performance.

The backing block frame 114 may be desirably formed of a material whose acoustic impedance matches with the neighboring elements, such as the active element 122 and the damping grease mixture 112. For example, the backing block frame 114 may be formed of a plastic material, such as epoxy resin, which is only illustrative. According to an exemplary embodiment, the backing block frame 114 may be made of a material that is hard enough to support the transducer body 120.

In addition, although not illustrated in FIG. 1, the backing block frame 114 may be provided with an injection port through which the damping grease mixture 112 is inserted into the backing block frame 114. Also, the backing block frame 114 may be further provided with a discharge port for checking whether the inside of the backing block frame 114 has been completely filled with the damping grease mixture 112 injected through the injection port. However, the injection port and the discharge port of the backing block frame 114 provided on the finished ultrasonic transducer 100 have to be hermetically sealed. Both the injection port and the discharge port may be detachably sealed or permanently sealed. The injection port and the discharge port will be described again with the description of a manufacturing method of the ultrasonic transducer.

The damping grease 112a that constitutes the damping grease mixture 112 is, like most grease, a buffer material against wear and corrosion or lubricating oil in a semi-solid state. All greases are formulated by mixing an oil and a viscosity increasing agent. The viscosity increasing agent holds the oil in place until shearing force is applied to the grease by, for example, lever, gear or detent. Then, the oil is released, to some degree, to lubricate the moving part. The difference between standard grease and the damping grease is the magnitude of resistance to shear stress. The damping grease is formulated with viscous (high-molecular-weight) synthetic oils, exhibiting a high internal shear stress resistance. It takes a degree of force to move parts through the damping grease, and there is little chance of free motion of the parts when the force is removed.

According to the exemplary embodiment, the type of the damping grease 112a is not particularly limited as long as the acoustic impedance of the damping grease mixture 112 matches well with the active element 122 and exhibits excellent acoustic absorption properties. For example, a mixture in which a base oil is mixed with Polytetrafluoroethylene (PEFE), so called Teflon, as a viscosity increasing agent may be used as the damping grease 112a. In this case, the base oil may be, for example, polyalphaolefin. The PTFE content may be 45-50% by volume relative to the total volume of the damping grease.

The filler 112b of the damping grease mixture 112 serves to increase acoustic impedance matching performance, as well as attenuation performance of the damping grease mixture 112. To this end, the filler 112b may use high-density powders. For example, metal powders of, for example, tungsten (W), manganese (Mn), lead (Pb), and zinc oxide (ZnO) may be used as the filler 112b. The filler 112b may be contained at a weight ratio of about 30 to 80% relative to the total weight of the damping grease mixture 112, and preferably about 40 to 70%.

The backing block 110 is provided with the ultrasonic transducer body 120 on its upper part. The ultrasonic transducer body 120 uses the active element 122 provided inside said ultrasonic transducer body 120 to generate ultrasonic waves, externally irradiate the ultrasonic waves to a particular point (e.g., an area to be diagnosed), receive, in turn, ultrasonic wave reflection and convert the reflected ultrasonic waves into electronic signals. The structure, shape, type and the like of the ultrasonic transducer body 120 may be implemented in various ways, and according to the exemplary embodiment, there are not particular limitations thereto. Thus, it will be understood that the description of the ultrasonic transducer body 120 is only illustrative. As described above, the ultrasonic transducer body 120 includes the lower electrode unit 121, the active element 122, the matching layer 124, and the lens part 125.

The lower electrode unit 121 is formed of a conductive material, including lower electrodes that are connected to one end of the active element 122. The lower electrodes may be composed of a conductive material with a low conductivity, such as copper, gold, silver, and the like. The shape, disposition pattern, thickness, and width of the lower electrodes may vary depending on the type and characteristics of the active element 122 and/or the ultrasonic transducer 100 that including the active element 122, and thus, in the exemplary embodiment, they are not particularly limited.

According to the present exemplary embodiment, the lower electrode unit 121 may have various configurations and patterns. For example, the lower electrode unit 121 that is interposed between the backing block 110 and the active element 122 may only include lower electrodes, and a printed circuit board (PCB) that is connected to said lower electrodes may be disposed on a side of the backing block 110. In this case, the lower electrodes may be each formed of a conductive metal foil, and may be arranged in a designated pattern, for example, a stripe pattern, and attached by adhesive or the like to a top surface of the backing block. The lower electrodes may be laminated and bonded in a flat manner along the top surface of the backing block 110. For example, each of the lower electrodes with a constant width and thickness may be in a strip shape, both ends of which extend from the sides to both edges of the backing block 110 along a first direction (elevation direction). The extended ends of the lower electrodes in strip shape may be respectively connected by wire bonding or the like to terminals of the PCB.

In another example, the lower electrode unit 121 that is interposed between the backing block 110 and the active element 122 may be configured to include a PCB with a designated pattern and lower electrodes that are formed on an upper part of the PCB so as to be electrically connected to the PCB. The PCB is not necessarily a substrate made of a rigid material, but may be a flexible PCB (FPCB) made of a soft material. The PCB may have various types of electrical components and wiring (which includes terminals connected to the lower electrodes) required for operation of the ultrasonic transducer 100.

According to the exemplary embodiment, a support substrate 130 may be further interposed between the backing block 110 and the lower electrode unit 121. In particular, the support substrate 130 takes a role to support the backing block 110 that is filled with the damping grease mixture 112, that is, to support the ultrasonic transducer body 120 located above the backing block 110. To this end, the support substrate 130 may be preferably made of a material having a designated hardness. In addition, the support substrate 130 may be preferably formed of a material having a similar acoustic impedance to that of the backing block 110. For example, the support substrate 130 may be formed of epoxy and high-density metal powders or metal oxide powders, but it is not limited thereto.

Such the support substrate 130 may be particularly useful, especially when the lower electrode unit 121 by itself cannot support the ultrasonic transducer body 120 since it is formed of a flexible PCB or the like.

The active element 122 generates an ultrasonic signal when energy is exerted by the voltage applied to both ends of the active element 122. The type of active element 122 may vary depending on the type of the ultrasonic transducer 100, which is not particularly limited in the exemplary embodiment. For example, the active element 122 may include a piezoelectric element. In response to voltage being applied, piezoelectric elements resonate and generate ultrasonic signals, and in response to an ultrasonic signal being received, the piezoelectric elements vibrate and generate electrical signals. Although the shapes or arrangement pattern of the piezoelectric elements are not particularly limited, the piezoelectric elements may be arranged in such a pattern that they correspond to the respective lower electrodes of the lower electrode unit 121 and are separate from each other. These piezoelectric elements may be bonded by adhesive or the like to the top surface of the lower electrode unit 121. For example, the piezoelectric elements may be arranged apart from each other at regular intervals along a second direction (azimuth direction). The piezoelectric elements may each be formed to have a specific thickness and the same cross-sectional area as that of the corresponding lower electrode. Also, the piezoelectric elements may be formed of single crystal of piezoelectric ceramic of lead zirconate titanate (PTZ) group, or a piezoelectric material composite resulting from combining said materials and a polymer material, or a piezoelectric material consisting of a polymer material which is represented by polyvinylidene fluoride (PVDF).

The upper electrode unit 123 may be disposed on the top surface of the active element 122 by being bonded by adhesive. For example, the upper electrode unit 123 may include upper electrodes which are formed each of a conductive metal foil and arranged apart from each other and bonded to the top surface of the corresponding active elements 122. In addition, the upper electrodes may each be formed to have a specific thickness and the same cross-sectional area as that of the corresponding active element 122. When the lower electrodes act as signal electrodes for transmission and reception of electrical signal, the upper electrodes may serve as ground electrodes.

The matching layer 124 may be disposed on the top surface of the upper electrode unit 123 by being bonded by adhesive. The matching layer 124 may take a role as a buffer to alleviate a problem such as image distortion due to a drastic change in acoustic impedance between the active elements 122 and the object to be examined. To this end, the matching layer 124 may be made of a material including epoxy resin, and formed of a single or multiple layers. Also, multiple matching layers 124 may be formed in such a manner that they correspond to the respective upper electrodes, and are separated from each other, while each matching layer is boned onto the top surface of the corresponding upper electrode. The separated matching layers 124 may each be formed to have a specific thickness and the same cross-sectional area as that of the corresponding upper electrode.

The lens part 125 includes an acoustic lens that functions as a focusing lens that focuses the ultrasonic waves generated by the active elements 122. The lens part 125 is not particularly limited in material and type. Also, a focal length of the lens part 125 may be determined according to a typical use of the ultrasonic transducer 100. The lens part 125 may be disposed above the matching layer 124. In addition, it is obvious that the shape of the lens part 125 shown in FIG. 1 is only illustrative, and the shape may be properly implemented by one of ordinary skill in the art in order to effectively focus the ultrasonic waves.

Hereinafter, experimental results regarding characteristics of the backing material of the ultrasonic transducer in accordance with the exemplary embodiment will be described. As described above, the backing material must have acoustic impedance that matches well with the active element, for example, a piezoelectric element, and exhibit excellent acoustic absorption properties. In the exemplary embodiment, a damping grease mixture is used as the backing material. As will be described later, the damping grease mixture is superior in terms of the acoustic absorption characteristic and acoustic impedance.

The experiment was carried out under the following conditions. First, Fluorocarbon Gel 868 of Nye lubricant was used as a damping grease of the damping grease mixture. This product uses polyalphaolefin as a base oil, and PTFE as a viscosity increasing agent. Depending on the product, there is a slight error in the PTFE content, which is about 40 to 50% by volume relative to the total volume of the damping grease. In addition, tungsten (W) was used as a filler of the damping grease mixture.

An experiment for measuring acoustic characteristics was performed using an acoustic characteristic measuring coupon. The acoustic characteristic measuring coupon was prepared in the following manner: Frist, an epoxy plate of 30 mm width, 30 mm length and 3 mm thickness was prepared, and then, guide blocks of designated thicknesses, for example, 1, 2, and 3 mm, were prepared, each of which was attached on upper and lower surface of the epoxy plates, respectively. Then, the damping grease mixture was injected between the guide blocks, which were thereafter sealed by tape, and then the acoustic characteristic measuring coupon was completed. In the present experiment, the amount of tungsten (W) contained in the damping grease mixture to be injected was varied, for which damping grease mixtures with 0 wt %, 5.5 wt %, and 51.9 wt % of tungsten were prepared.

The acoustic characteristic measurement was performed in a typical manner. More specifically, for each sample, an output voltage relative to time was measured by using pulse/receiver. Signal attenuation was calculated as an output voltage by using a burst wave of 20 cycles. The measurement results are as shown in Table 1 below, which illustrates said results to be compared with the existing product (existing acoustic absorbing material).

TABLE 1

| | | | Longitudinal | Longitudinal | Longitudinal |
|---|---|---|---|---|---|
| | Filler | Density | Velocity | Attenuation | Impedance |
| Classification | [wt %] | [g/cm³] | [m/s] @3.5 Mhz | [db/mm] @3.5 Mhz | [Mrayl] |
| Existing | — | 1.710 | 1.815 | 11.01 | 3.11 |
| product | | | | | |
| Present | 0 | 1.160 | 1.238 | 4.31 | 1.44 |
| invention | 5.0 | 1.217 | 2.497 | 21.67 | 1.60 |
| | 51.9 | 2.270 | 1.296 | 70.0 | 2.94 |

Referring to Table 1, the damping grease mixture in which a damping grease was mixed with 51.9 wt % of tungsten powder as a filler has an acoustic impedance of 2.94 Mrayl, which is similar to the characteristic of the existing acoustic absorbing material. Also, it is shown that as the amount of tungsten powder contained in the damping grease mixture increases, the attenuation also increases. Particularly, in the case of the damping grease mixture with 51.9 wt % of tungsten powder, it is seen that the attenuation is equal to or greater than 70 [db/mm], which indicates that said damping grease mixture exhibits an excellent acoustic absorbing characteristic that is about seven times greater than that of the exiting acoustic absorbing material.

Therefore, if the damping grease mixture in accordance with the exemplary embodiment is used as a backing material, a product having a thickness of one-seventh of the thickness of the existing product may achieve the same attenuation effect as the exiting product. As such, if the damping grease mixture is used as a backing material, it is possible to create a compact backing block, which is effective in producing a compact ultrasonic transducer with an excellent performance.

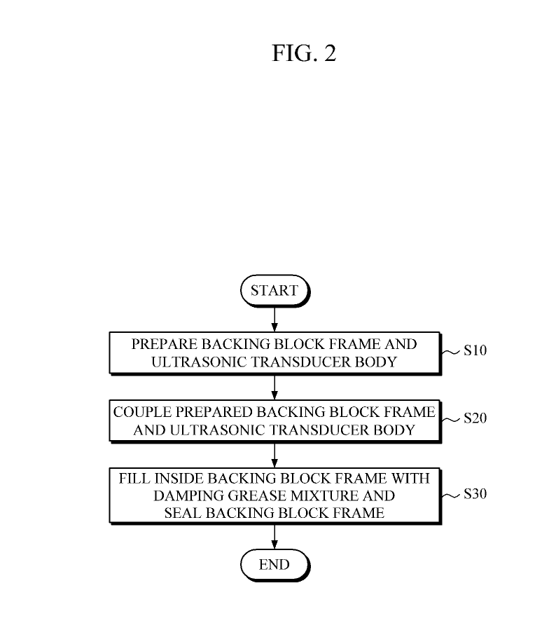

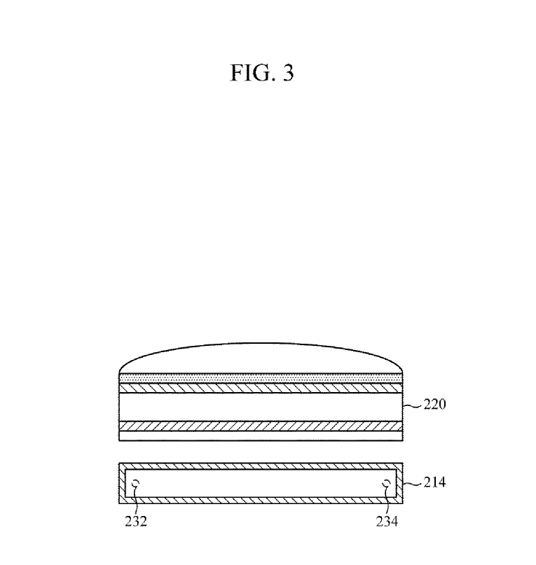

Then, a method for manufacturing an ultrasonic transducer having the damping grease mixture in accordance with the exemplary embodiment will be described. FIG. 2 is a flowchart illustrating a method for manufacturing an ultrasonic transducer according to an exemplary embodiment of the present invention. FIGS. 3 to 5 are diagrams schematically illustrating procedures for manufacturing the ultrasonic transducer of FIG. 1 according to the method of FIG.

2.

Referring to FIGS. 2 and 3, the backing block frame 214 and the ultrasonic transducer body 220 are prepared, as depicted in S10. Hereinafter, it may be construed that the ultrasonic transducer body 220 includes both the ultrasonic transducer body 120 and the support substrate 130. However, if the lower electrode unit is formed as a rigid PCB, said ultrasonic transducer body 220 may not include the support substrate 130. In the present exemplary embodiment, the method for manufacturing the ultrasonic transducer body 220 is not particularly limited. For example, the lower electrode unit, the active elements, the upper electrode unit, and the matching layer may be sequentially laminated on the support substrate, and the lens part may be bonded onto the matching layer to thereby form the ultrasonic transducer body 220.

Then, the backing block frame 214 may have a hollow space inside that serves as a container to accommodate the damping grease mixture, and the backing block frame 214 may be formed of epoxy resin. In drawings, the backing block frame 214 is illustrated as a rectangular block shape; however, this is only illustrative, as described above. Also, the backing block frame 214 has the injection port 214 through which the damping grease mixture is injected, wherein the injection port 214 is not particularly limited in size or location.

According to exemplary embodiments, the backing block frame 214 may further include a discharge port 234. The discharge port 234 is provided for checking whether the internal hollow space of the backing block frame 214 has been filled with the damping grease mixture. For example, it may be confirmed that the inside of the backing block frame 214 has been completely filled by checking if the damping grease mixture injected through the injection port 232 into the backing block frame 214 is discharged through the discharg port 234. To completely fill the inside of the backing block frame 214, the discharge port 234 may be preferably located opposite to the injection port 232 (e.g., as shown in FIG. 3, if the injection port 232 is located at the left end of the backing block frame 214, the discharge port 234 may be located at the right end of the backing block frame 214). However, the discharge port 234 is only an optional element, and hence said discharge port 234 may not be provided, as long as it can be checked whether the inside of the backing block frame 214 has been filled.

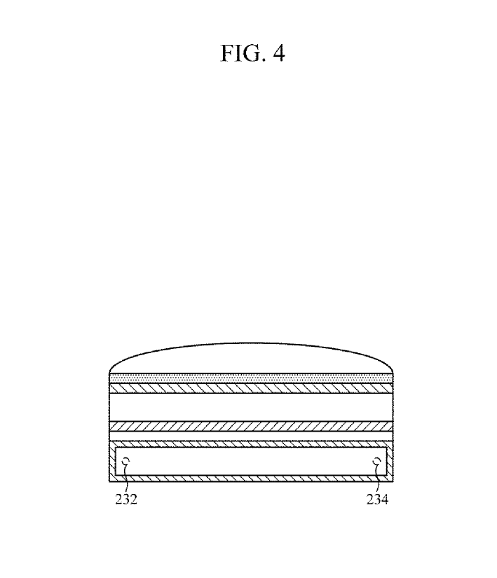

Referring to FIGS. 2 and 4, the prepared backing block frame 214 is coupled to the ultrasonic transducer body 220, as depicted in S20. In the present exemplary embodiment, a method for coupling the backing block frame 214 and the ultrasonic transducer body 220 is not particularly limited, and they may combined to each other using adhesive or other attachment means. In addition, the backing block frame 214 may be coupled to a lower portion of the ultrasonic transducer body 220, that is, a lower surface of the lower electrode unit or substrate (refer to FIG. 1). The coupling of the backing block frame 214 and the ultrasonic transducer body 220, as depicted in S20, may be performed after S30 which will be described below.

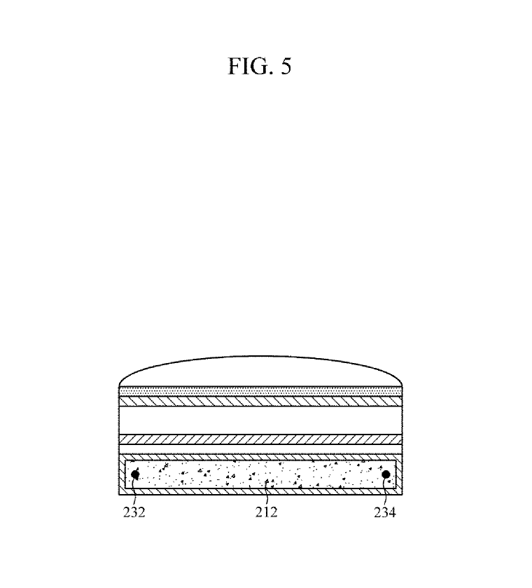

Then, referring to FIGS. 2 and 5, the inside of the backing block frame 214 is filled with the damping grease mixture 212 and then hermetically sealed, as depicted in S30. The damping grease mixture 212 may be injected into the backing block frame 214 through the injection port 232. Once the inside of the backing block frame 214 is completely filled, the injection port 232 may be openably sealed by an appropriate closing means (e.g., a cover) or may be permanently sealed. The means for injecting the damping grease mixture 212 is not particularly limited, and, for example, a dispenser may be used.

To achieve more effective acoustic absorption characteristic, as well as prevent noise from occurring due to an empty space, the damping grease mixture 212 may preferably fill completely the inside of the backing block frame 214. If the backing block frame 214 has the discharge port 234 and the damping grease mixture 212 is discharged through said discharge port 234, it may be determined that the backing block frame 214 has been completely filled with the damping grease mixture 212. Alternatively, if the volume of the backing block frame 214 is known, the damping grease mixture 212 may be accurately measured before injection, or if the backing block frame 214 is made of a transparent material, whether the backing block frame 214 has been completely filled with the damping grease mixture 212 may be visibly checked.

As such, according to the method for manufacturing the ultrasonic transducer in accordance with the exemplary embodiments of the present invention, the ultrasonic transducer may be manufactured by injecting the damping grease mixture into the backing block frame. For example, the backing block frame is boned onto a lower part of the ultrasonic transducer body and then the damping grease mixture is injected, or the damping grease mixture is first injected into the backing block frame and then the backing block frame is bonded onto the lower part of the ultrasonic transducer body. An injection means, such as a dispenser, may be used to inject the damping grease mixture.

As apparent from the above description, according to the exemplary embodiments, since it is possible to manufacture the backing block by injecting the damping grease mixture into the backing block frame using a dispenser or the like, processes for preparing a large block of material used for the backing block and shaping the material block to a form of the backing block are not required, and hence it is possible to simplify the manufacturing process for the ultrasonic transducer and reduce the manufacturing cost.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

### INDUSTRIAL APPLICABILITY

The present invention can be efficiently applied to ultrasonic transducer-related industries.

1. An ultrasonic transducer comprising:
an ultrasonic transducer body configured to externally irradiate ultrasonic waves generated from an active element through a lens part and receive reflected waves of the externally irradiated ultrasonic waves to convert the reflected waves into electrical signals; and
a backing block bonded to an opposite side of the lens part at the ultrasonic transducer body so as to attenuate the ultrasonic waves,
wherein a backing material of the backing block is comprises of a damping grease mixture.

2. The ultrasonic transducer of claim 1, wherein the damping grease mixture is a material in which metal powder is mixed as a filler by using the damping grease as a dispersion medium.

3. The ultrasonic transducer of claim 2, wherein the damping grease is a mixture in which polytetrafluoroethylene (PTFE) is mixed as a viscosity increasing agent

4. The ultrasonic transducer of claim 3, wherein the PTFE is added at a volume ratio of 45-50% relative to a total volume of the damping grease mixture.

5. The ultrasonic transducer of claim 3, wherein the metal powder contains at least one of tungsten (W), manganese (Mn), lead (Pb), and zinc oxide (ZnO).

6. The ultrasonic transducer of claim 5, wherein the metal powder is contained at a weight ratio of 40-70% relative to a total weight of the damping grease mixture.

7. The ultrasonic transducer of claim 1, further comprising:
a support substrate interposed between the ultrasonic transducer body and the backing block so as to support the ultrasonic transducer body.

8. The ultrasonic transducer of claim 1, wherein the backing block comprises a backing block frame having an internal hollow space, and the damping grease mixture that fills inside the backing block frame.

9. A method for manufacturing an ultrasonic transducer, comprising:
preparing an ultrasonic transducer body and a backing block frame;
bonding the prepared ultrasonic transducer body and the backing block frame to an opposite side of a lens part of the ultrasonic transducer body; and
injecting a damping grease mixture into the backing block frame through an injection port on the backing block frame.

10. The method of claim 9, wherein in the injection of the damping grease mixture, the damping grease mixture is injected using a dispenser.

11. The method of claim 10, wherein in the injection of the damping grease mixture, the damping grease mixture is injected until the damping grease mixture is discharged through a discharge port on the backing block frame, and thereafter, the injection port and the discharge port are sealed.

12. The method of claim 9, wherein the bonding and the injection can be performed in a reverse order.
